(19) United States
(12) Patent Application Publication
(10) Pub. No.: US 2026/0177650 A1
(43) Pub. Date: Jun. 25, 2026

(54) APPARATUS AND METHOD FOR ISOLATING SHIM ELEMENTS

(71) Applicant: Siemens Healthineers AG, Forchheim (DE)

(72) Inventor: Johann SUKKAU, Herzogenaurach (DE)

(73) Assignee: Siemens Healthineers AG, Forchheim (DE)

(21) Appl. No.: 19/429,042

(22) Filed: Dec. 22, 2025

(30) Foreign Application Priority Data
Dec. 23, 2024 (DE) 10 2024 212 289.0

(51) Int. Cl. G01R 33/3875

(52) U.S. Cl. CPC G01R 33/3875

(57) ABSTRACT

An apparatus for isolating shim elements includes a cassette and a separation apparatus. The cassette is configured to accommodate and/or store a plurality of shim elements. The shim elements are arranged in the cassette in the form of a stack. The separation apparatus is configured to isolate a shim element, of the plurality of shim elements, out of the cassette via a horizontal sideways movement.

### CROSS-REFERENCE TO RELATED APPLICATION(S)

The present application claims priority under 35 U.S.C. § 119 to German Patent Application No. 10 2024 212 289.0, filed Dec. 23, 2024, the entire contents of which are incorporated herein by reference.

### FIELD

One or more example embodiments of the present invention relate to an apparatus for isolating shim elements and a method for isolating shim elements.

### BACKGROUND

In magnetic resonance tomography (MRT) shim elements, also called shims or shim plates, are of crucial importance for homogenizing magnetic fields. Shimming refers to the process of adjusting a magnetic field, in the context of magnetic resonance tomography, in order to minimize image artifacts and improve the image quality. Various methods of shimming are known for this, including the basic shim or passive shimming. In passive shimming ferromagnetic materials are placed permanently in a magnetic field. Active shimming typically includes the use of electromagnetic coils which are regulated by a control current in order to adjust the magnetic field dynamically.

The shim elements are arranged in what are known as shim trays, which are arranged on the MRT device in order optimally to align and/or balance the magnetic field. A technical challenge when using shim elements is to isolate the shim elements. Shim elements are typically produced in large quantities and are afterwards for example stored and/or transported in oil-soaked form, in order to prevent possible corrosion of the shim elements. Corrosion could lead to an impairment of the properties of the shim elements and thus to an uncontrolled shim. Other corrosion countermeasures are conceivable, for example packaging designed for this purpose. However, these countermeasures, in particular soaking the shim elements in oil, and the properties of the shim elements as such, mean that the shim elements may adhere strongly to one another. While manual separation is known and easy for an experienced person, adherence of the shim elements presents an unresolved challenge for mechanical separation apparatuses. The mechanical isolation must moreover be effected so that a precise and reliable separation of the shim elements is ensured before they are for example arranged in the shim trays to shim a magnet. An incorrect and/or indeterminate isolation can lead to an undefined influence on the magnet of a magnetic resonance device and thus possibly to inaccurate imaging.

### SUMMARY

An object of one or more example embodiments of the present invention is hence to provide an improved apparatus and method for reliable and efficient isolation of shim elements.

In accordance with one or more example embodiments of the present invention, an apparatus for isolating shim elements is proposed. The apparatus includes a cassette for accommodating and/or storing a plurality of shim elements. The shim elements are arranged in the cassette in the form of a stack. The apparatus includes a separation apparatus for isolating a shim element. The separation apparatus is designed to isolate a shim element from the plurality of shim elements via a horizontal sideways movement out of the cassette.

In particular, the shim elements are aligned horizontally and arranged vertically one above the other in the cassette. The horizontal alignment of the shim elements and the vertical arrangement one above the other can in this case be effected in particular along and/or orthogonally to an axis of the cassette. Such an axis of the cassette can for example be a center axis, i.e. in particular a surface normal of a side wall and/or base of the cassette. In other words, the cassette can also be spatially arranged tilted by for example 10° to a baseplate and/or the direction of gravity.

A shim element is in particular a component designed for the adjustment and homogenization of magnetic fields, in particular in magnetic resonance tomography (MRT). For this purpose, the shim element can in particular have a particular shape or dimension. A shim element is typically configured two-dimensionally as a sheet metal element with square dimensions. The shim properties of the shim element are typically determined via the thickness/height, i.e. the material thickness in the surface normal direction of the shim element. Shim elements typically consist of ferromagnetic materials. However, other magnetically influencing materials are also conceivable for shim elements. Thanks to the known and/or determinable properties of the shim element it is possible to carry out a precise magnetic correction of a magnetic field by positioning the shim element (and/or multiple shim elements). Shim elements can exist in different shapes, sizes and thicknesses/heights, to meet different requirements and magnetic field anomalies.

The cassette can in particular be a container for storing and transporting shim elements. The cassette can accordingly enable a plurality of shim elements to be handled and/or stored. The cassette can preferably be designed as a cuboid container. In particular, the cassette can include a cavity bounded by walls for accommodating shim elements. The cassette is in particular designed to accommodate and/or fix a plurality of shim elements horizontally one above the other in the cassette in the form of a stack. For this, the cassette can in particular have guide elements in the form of guide rails, for example. Moreover, the cassette can in particular include a lifting apparatus for the vertical movement of the stack of shim elements, in particular for raising it. For example, the cassette can include one or more lifting cylinders, which are designed and/or arranged to raise and/or lower a baseplate on which a stack of shim elements can be placed. The lifting apparatus can likewise be included in the apparatus. For example, the apparatus can include a lifting cylinder which from outside the cassette can act on a baseplate for the vertical movement thereof.

The separation apparatus includes in particular an element for fixing a shim element, for example a suction element and/or a magnetic element. Moreover, the separation apparatus can include a movement apparatus, in particular for moving the element to fix a shim element. The separation apparatus is in particular designed to fix a shim element via the element, in particular via a suction element and/or a magnetic element, and with a horizontal sideways movement to separate it from the stack of shim elements and to remove the shim element from the cassette. In other words, via the separation apparatus a shim element can be separated from the plurality of shim elements in the cassette and pushed and/or pulled sideways out of the cassette. Besides the preferred isolation of a shim element by a horizontal sideways movement, other separation and/or isolation movements are also conceivable. For example, it is conceivable for a shim element to be removed from the cassette at a predetermined angle. Moreover, it is conceivable for example for a shim element to be raised and/or tilted and then to be transported out of the cassette with a movement.

The apparatus for isolating shim elements can advantageously enable the reliable, precise and automatic separation of shim elements. Even if shim elements adhere to one another due to oil-soaked storage or material-related properties, the proposed apparatus can enable efficient handling. Moreover, thanks to the automatic isolation enabled, damage to the shim elements and/or incorrect separation can for example be minimized compared to manual isolation. The apparatus can moreover enable the automatic placement of the shim elements in shim trays by for example a further apparatus, for which isolated shim elements may be necessary as output material. In particular, the apparatus can enable a reduction in manual manufacturing steps, in particular when producing and/or filling shim trays, and hence can increase the efficiency of the production process.

In accordance with one aspect of embodiments of the present invention, the apparatus further includes at least one guide element. The guide element is designed to guide the horizontal sideways movement of one shim element of the plurality of shim elements.

The guide element is in particular designed to guide, control, monitor and/or direct a movement, preferably accurately, of a shim element, in particular passively. In other words, thanks to the guide element the specification of a direction of the isolation can be effected by the horizontal sideways movement. Expressed differently, a directed movement, in particular an isolation movement, of a shim element, can be effected by the guide element. In particular, the guide element can comprise a sliding surface which is designed to enable a friction-reduced movement of a shim element along the sliding surface. Furthermore, the guide element can include a guide rail, a bar and/or an otherwise designed element for guiding a shim element. In particular, the guide element can enable a shim element to be pressed onto the guide element, in particular via a lifting apparatus. The guide element can be designed to exert a force, in particular a compressive force, on the stack of shim elements. The guide element is preferably arranged in the apparatus opposite the lifting device. The guide element is preferably arranged in the cassette such that the upper or lower shim element of the stack of shim elements abuts the guide element. The horizontal sideways movement of a shim element out of the cassette can preferably be effected along the guide element. The apparatus including the guide element is designed to remove the upper shim element, in the direction of the separation apparatus, abutting the sliding element out of the cassette via the separation apparatus.

The guide apparatus can advantageously enable the shim elements to be moved in a predetermined direction during the isolation. It can therefore provide reliable and damage-free isolation thanks to a stabilized horizontal sideways movement of the shim elements out of the cassette.

In accordance with one aspect of embodiments of the present invention, the apparatus further includes at least one fixing apparatus. The fixing apparatus is designed to fix the shim elements in the cassette.

In particular, the fixing apparatus is designed to fix the plurality of shim elements in the cassette, less the shim element to be isolated.

Furthermore, in accordance with one aspect of embodiments of the present invention, in particular assigned to the previous aspect, the fixing apparatus includes at least one magnet. The magnet is designed to fix the stack of shim elements magnetically in the cassette. In particular, the magnet is designed to fix the plurality of shim elements magnetically in the cassette, less the shim element to be isolated.

In other words, thanks to the fixing element the stack of non-isolated shim elements can, with the exception of the shim element to be isolated, in particular located at an end of the stack, in particular be held in the cassette. In particular, for this purpose the fixing element can be designed to exert a holding force on the stack of shim elements. The holding force can in particular be a compressive force and/or for example a magnetic force. For example, the fixing apparatus can be included in the cassette. For example, the fixing apparatus can include guide rails of the cassette, suction cups generating negative pressure and/or displaceable/adjustable walls of the cassette.

The magnet can in particular include a permanent magnet and/or an electromagnet. In particular, the magnet can be designed to apply a magnetic holding force to the shim element. In particular, the magnet can be designed to generate a controllable magnetic holding force.

The fixing apparatus can be arranged in particular outside the cassette laterally. In particular, the fixing apparatus can be included in the cassette. In particular, the fixing apparatus can be encompassed by a wall of the cassette, in particular a side wall. In particular, the fixing apparatus can be arranged so that the fixing apparatus is arranged horizontally laterally at the level of the stack of the plurality of shim elements.

In other words, thanks to the fixing element it can advantageously be enabled for only one shim element at a time to be removed from the cassette, without bringing the stack of non-isolated shim elements with it. In particular, the fixing element can also ensure the precise and efficient isolation of just one shim element. A fixing element designed as a magnet can advantageously in particular enable contactless fixing of the stack of shim elements.

Furthermore, in accordance with one aspect of embodiments of the present invention, the fixing apparatus includes at least one selection element. The selection element is designed to fix the stack of shim elements mechanically in the cassette.

In particular, the selection element is designed to fix the plurality of shim elements mechanically in the cassette, less the shim element to be isolated.

The selection element can be designed in particular as a metal sheet, separating edge, blade and/or panel. In particular, the selection element can be made of a non-magnetic material. In particular, the selection element can be arranged on the side of the cassette, in particular on a wall on which the cassette is not designed to be closed. In particular, the selection element can be encompassed by a wall of the cassette, in particular a cassette side wall.

In particular, the mechanical fixing of the stack of the plurality of non-isolated shim elements can advantageously enable the efficient isolation of the shim elements. In other words, thanks to the selection element shim elements which adhere to the shim element fixed and/or selected by the separation apparatus can be peeled off.

In accordance with a preferred aspect of embodiments of the present invention, the fixing apparatus is arranged in relation to the cassette and the guide element such that a gap is formed between the fixing apparatus and the guide element. The gap has at least a clearance in accordance with the height of a shim element. The separation apparatus is designed to remove the shim element to be isolated out of the cassette through the gap. In particular, the selection element can be arranged on the cassette such that a gap with a predetermined width arises between the selection element and an edge of the cassette. In particular, the fixing apparatus is arranged in relation to the stack of the plurality of shim elements so that the horizontal sideways movement of the shim element to be isolated is guided via the fixing apparatus.

The formation of a gap between selection element and guide element (and/or an edge of the cassette) in this case advantageously enables only a predetermined number of shim elements to be removed from the cassette at the same time by the horizontal sideways movement.

In accordance with a preferred aspect of embodiments of the present invention, the fixing apparatus is designed to be adjustable. The gap between the fixing apparatus and the guide element can be adjusted as a function of the height of the shim elements.

In particular, the selection element can be designed to be vertically movable or displaceable. In particular, the selection element can be attached to the cassette in a hinged manner. In other words, the selection element can be designed to be hinged to the side, so that for example the shim elements can be removed out of or inserted into the cassette.

The adjustable design of the selection element can advantageously enable a predetermined adjustment of the gap. As a result, the cassette or the apparatus for isolating differently designed shim elements, in particular with regard to their height, can be used.

In accordance with one aspect of embodiments of the present invention, the separation apparatus includes a suction element. The suction element is designed to fix a shim element by generating a negative pressure.

The suction element can preferably be designed in the form of a suction cup and/or a vacuum gripper. The suction element is preferably designed to create a negative pressure, partial vacuum and/or vacuum, resting on a surface of the shim element. In particular, the generation of this negative pressure, partial vacuum and/or vacuum can be achieved by connecting the suction element to a negative pressure and/or vacuum generator. The connection between the suction element and the negative pressure and/or vacuum generator can preferably be effected via a hose connection. The generation of a negative pressure for fixing the shim element can also in particular be effected mechanically, similarly to a typical suction cup. By applying a pressure to the suction element, for example by the selection apparatus, the generation of a negative pressure can be effected. In other words, the suction element is designed to suck a shim element in. In addition, for example by reversing the negative pressure generator to apply a positive pressure, the suction element can be designed to release the fixing of a shim element again at a controllable time after fixing.

The separation apparatus including a suction element can advantageously enable the precise and efficient handling and fixing of the shim element to be isolated. In particular, the secure fixing of the shim element by the suction element can enable the horizontal sideways movement.

In accordance with one aspect of embodiments of the present invention, the separation apparatus includes a magnetic element. The magnetic element is designed to fix a shim element magnetically.

The magnetic element can preferably be designed in the form of a permanent magnet and/or an electromagnetic gripper. The magnetic element is preferably designed, resting on a surface of the shim element, to generate an attractive force between the shim element and the magnetic element by applying a magnetic field. In particular, the magnetic field generated by the magnetic element can be controlled and/or switched on and off in this case. The generation of the magnetic field by the magnetic element can in particular be effected by an electromagnet. In other words, a shim element can be fixed and/or gripped by the magnetic element by switching on the magnetic field. In addition, for example by switching off the magnetic element, the magnetic element can be designed to release the fixing of a shim element again at a controllable time after fixing.

The separation apparatus including a magnetic element can advantageously enable the precise and efficient handling and fixing of the shim element to be isolated. In particular, the secure fixing of the shim element by the magnetic element can enable the horizontal sideways movement.

In accordance with one aspect of embodiments of the present invention, the separation apparatus includes a mechanical sliding apparatus.

The sliding apparatus can in particular be arranged on the cassette and/or included in the cassette. The sliding apparatus can in particular include a slide that can be moved on a track and/or linearly. The sliding apparatus can in particular be designed to guide a shim element out of the cassette by applying a compressive force to an edge and/or surface of the shim element. The sliding apparatus can include a motorized drive, a hydraulic drive and/or a pneumatic drive. In particular, the slide can be designed so that it can be moved by the drive. For example, the sliding apparatus can be designed as a linear actuator.

Thanks to the sliding apparatus the isolation of the shim elements can advantageously be effected by a simple, controlled movement of a slide. A movement of the separation apparatus as such can as a result for example be minimized and the efficiency of the isolation increased.

In accordance with one aspect of embodiments of the present invention, the apparatus further includes a lifting apparatus. The lifting apparatus is designed to raise and/or lower a plurality of shim elements in the cassette in a vertical direction.

The lifting apparatus in particular includes a drive apparatus and a platform. The drive apparatus is in particular designed to displace the platform, preferably by a vertical lifting movement. The platform is in particular displaceably guided and/or mounted in the cassette. The platform can in particular be designed to accommodate a stack of non-isolated shim elements. Via the platform moved by the drive apparatus the stack of shim elements in the cassette can in particular be raised and/or lowered in the vertical direction. For example, the lifting apparatus can include a hydraulic cylinder, a spindle drive and or a linear drive. For example, the lifting apparatus can be designed similarly to a typical lifting platform.

Thanks to the lifting apparatus it can advantageously be ensured that the non-isolated shim elements can be reliably supplied to the separation apparatus. Via the lifting apparatus the stack of shim elements can advantageously likewise be pressed onto an element of the apparatus (for example a guide element) and/or of the cassette.

In accordance with one aspect of embodiments of the present invention, the apparatus further includes a movement apparatus. The separation apparatus can be moved via the movement apparatus.

In accordance with a preferred aspect, the movement apparatus includes at least two linear axes. The separation apparatus can be moved via the movement apparatus, in particular the linear axes, in a first and a second direction.

In accordance with a further preferred aspect of embodiments of the present invention, the movement apparatus includes at least one robot arm. The separation apparatus can preferably be moved via the movement apparatus, in particular the robot arm, in a set movement volume.

In particular, via the movement apparatus the separation apparatus can be moved and/or displaced to a position (inside) the apparatus. In particular, via the movement apparatus a positioning of the separation apparatus can be effected, so that the separation apparatus can be placed at/on the shim element to be isolated. In other words, the movement apparatus enables the separation unit to approach a shim element. In particular, the horizontal sideways movement can be executed by the movement apparatus. For this purpose the movement apparatus can in particular be connected to a control and/or computing unit. The control and/or computing unit can in particular enable the movement apparatus to be controlled. In particular, the control and/or computing unit can enable the separation apparatus to be controlled by the movement apparatus. The movement apparatus can preferably be connected to the control and/or computing unit, for example via a cable connection. The control and/or computing unit can preferably be designed to send control signals to the movement unit and/or separation apparatus.

In a preferred form of embodiment two linear axes are in particular provided. However, three and/or more linear axes are also conceivable. A linear axis is typically designed to convert a circular movement generated by a motor into a linear movement along an axis. Thanks to this linear movement along an axis a linear axis can in particular be designed to move and/or displace an object, in particular the separation apparatus. In other words, an object can be pulled, pressed, raised, lowered or tilted along a track via a linear axis. In particular, linear axes can be arranged nested, linked and/or connected. This can enable an object to be moved and/or displaced in more than one direction.

A linear axis can typically consist of the following components: a roller, a profile, a sensor unit, for example a magnetically encoded and/or a visual position measuring system, a slide, a control unit, a sliding element and/or magnets. One (or more) rollers can here preferably enable a movement of a slide in a profile. For example, a sliding element can however also be provided and/or included in the slide. The control is preferably effected via a sensor unit in conjunction with a control unit. In this case, the control unit preferably receives measured signals from the sensor. The control unit is in particular designed to analyze the measured signals from the sensor and/or to send a corresponding movement signal to the linear axis, in particular the moving slide and/or to the drive unit/motor.

A robot arm typically consists of the following components: an articulation, a motor, a control unit, a sensor, an end effector and an arm element. The sensor can in particular be designed to detect the position and movement of the robot arm and/or of a part of the robot arm, as well as of the surrounding area. The sensor can for example include a rotary encoder, force sensor and/or camera. The motor can in particular be designed to drive the articulations and/or to move the arm. The motor can comprise an electric, hydraulic and/or pneumatic drive. The end effector can in particular be a tool and/or an apparatus at the end of an arm. In particular, the end effector can include the separation apparatus. The control unit can in particular include microprocessors and a program product for controlling the robot arm, in particular for controlling the articulations and/or motors. The articulation can in particular be designed as a rotary articulation and/or pivotable articulation.

In particular, a movement apparatus designed with linear axes can enable the robust and reliable movement of the separation apparatus. For example, linear axes enable easy control and highly defined movement speeds, so that the efficient isolation of the shim elements can be enabled.

In particular, a movement apparatus designed with a robot arm can enable the flexible movement of the separation apparatus. For example, this allows for more degrees of movement of the shim element. Thus for example a rotation of shim elements fixed by the separation apparatus and/or a further deposit radius for isolated shim elements can be enabled. Besides the horizontal sideways movement, the movement apparatus, which is designed as a robot arm, also in particular makes other movements conceivable, for example an angled shear movement.

In accordance with one aspect of embodiments of the present invention, the apparatus further includes a deposit cassette. The deposit cassette is designed to accommodate isolated shim elements and optionally intermediate elements. The deposit cassette, optionally in combination with intermediate elements, is designed to stock a plurality of isolated shim elements.

The deposit cassette, optionally in combination with intermediate elements, is designed in particular to stock a plurality of isolated shim elements in the form of a stack. The deposit cassette can in particular be designed similarly and/or structurally identically to the cassette. However, the deposit cassette can also in particular be designed such that a stock of shim elements arranged one above the other in the form of a stack is prevented. In particular, the deposit cassette can be designed such that the isolated shim elements can be offset and/or not stacked or stocked directly one above the other and/or not resting on one another. For example, the deposit cassette can include one and/or multiple walls with bulges, edges, undercuts and/or recesses which can accommodate one or more shim elements.

However, the isolated shim elements are preferably stacked separately in the deposit cassette via intermediate elements. The intermediate elements are preferably made of plastic. Via the intermediate elements, the shim elements can preferably be prevented from directly adhering to one another when stored one above the other.

The at least one apparatus including a deposit cassette can advantageously enable the more efficient isolation of the shim elements thanks to the improved storage of the shim elements. Thanks to the deposit cassette it can be ensured that following the isolation the shim elements can be supplied individually to subsequent steps/processes, without for example the shim elements re-adhering to one another.

Moreover, in accordance with embodiments of the present invention, a method for isolating shim elements via an apparatus in accordance with one of the above-described aspects is proposed. The method includes removing at least one isolated shim element from the cassette.

The method can include multiple steps. One step can include removing a shim element from the cassette via a horizontal sideways movement. A further step can include depositing an isolated shim element into a deposit cassette and/or another apparatus for storing isolated shim elements. A further step can moreover include separating and/or detaching a shim element out of/from a plurality of shim elements, in particular arranged as a stack. For this purpose, a shim element can optionally be fixed via a separation apparatus. Moreover, the stack of shim elements can optionally be fixed (or in other words held). A further step can include the approach and/or pressing of one or more shim elements, in particular a stack, onto a guide element, in particular via a lifting apparatus.

The advantages of the proposed method substantially correspond to the advantages of the proposed apparatus. Features, advantages or alternative forms of embodiment/aspects of the apparatus can likewise be transferred to the other claimed subject matters and vice versa.

### BRIEF DESCRIPTION OF THE DRAWINGS

Further advantages, features and details of the present invention emerge from the exemplary embodiments described below and on the basis of the drawings. Parts corresponding to one another are provided with the same reference characters in all the figures.

In the drawings:

FIG. 1 shows a schematic representation of a form of embodiment of the proposed apparatus for isolating shim elements,

FIG. 2 shows a schematic representation of a further form of embodiment of the proposed apparatus for isolating shim elements,

FIG. 3 shows a schematic representation of a further form of embodiment of the proposed apparatus for isolating shim elements,

FIG. 4 shows a schematic representation of a further form of embodiment of the proposed apparatus for isolating shim elements with a deposit cassette in a first view,

FIG. 5 shows a schematic representation of a further form of embodiment of the proposed apparatus for isolating shim elements with a deposit cassette in a second view,

FIG. 6 shows a three-dimensional schematic representation of a further form of embodiment of the proposed apparatus for isolating shim elements,

FIG. 7 shows a block diagram of a method for isolating shim elements.

### DETAILED DESCRIPTION

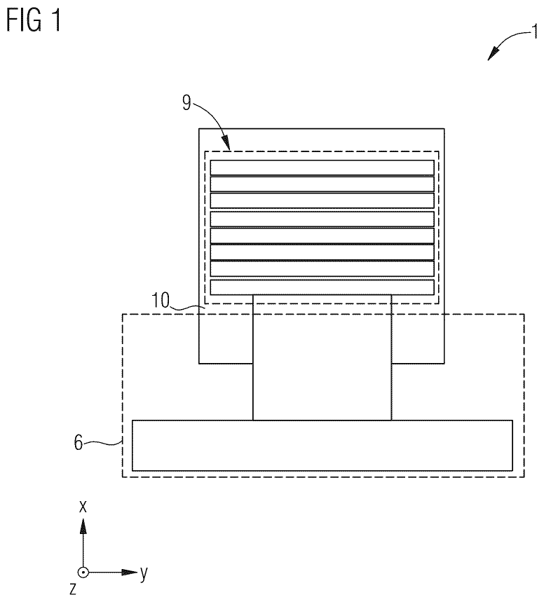

FIG. 1 shows a schematic representation of the proposed apparatus 1 for isolating shim elements 9 in a first form of embodiment. The apparatus 1 of this form of embodiment includes a cassette 10 and a separation apparatus 6. A plurality, in particular a stack, of shim elements, will be referred to below as shim elements 9, while a shim element will be illustrated via the reference character 9′.

Via the shim elements 9, a minimization of image artifacts and an improvement in image quality in particular in magnetic resonance tomography systems can be achieved. In particular, the defined placement of the shim elements 9 inside/on a magnet of a magnetic resonance tomography system can ensure a uniform and stable magnetic field. Shim elements 9 are typically of high magnetic permeability and should be corrosion-resistant to ensure their functionality and longevity. Hence shim elements can have a coating containing corrosion protection. Due to these properties, the shim elements 9 may adhere together, in particular if the shim elements 9 are present one above the other, as shown for example, in the form of a stack. For storage and/or stocking, the shim elements 9 can be placed and/or transported in a cassette 10. At least one cassette 10 can be included in the apparatus 1. In particular, the apparatus 1 and/or the cassette 10 can be designed so that a cassette 10 can be fitted, removed and/or replaced in the apparatus 1. Moreover, multiple cassettes 10, in particular containing different shim elements 9, can also in particular be included in the apparatus. The cassette 10 can be designed in particular in the form of a cuboid and/or a cylinder. In particular, the cassette 10 can have multiple wall elements, which in particular bound the cassette. The cassette 10 can in particular have a side and/or place which enables a shim element 9′ to be removed by a separation apparatus 6.

The additionally included separation apparatus 6 can be arranged above the cassette, in particular in a vertical direction (characterized by x in FIG. 1). The separation apparatus 6 can preferably be arranged opposite a side of the cassette that is designed to be open and/or is accessible. The separation apparatus 6 can in particular be designed to be displaceable and/or movable. As a result, the separation apparatus 6 can approach the cassette 10 and/or in particular a shim element 9′. The shim element 9′ can be fixed via the separation apparatus 6, for example via an included vacuum gripper. The shim element 9′ can be guided out of the cassette 10 via the separation apparatus 6 by a horizontal sideways movement. The horizontal sideways movement can preferably be effected by a movement of the separation apparatus 6. However, it is also conceivable for example for the cassette to be displaced in respect of the separation apparatus 6, in order to guide the shim element out of the cassette 10. In particular, the horizontal sideways movement can be effected on the level (in the y-direction). However, an angled sideways movement, for example a sideways movement inclined by 10 degrees to the horizontal, is also conceivable.

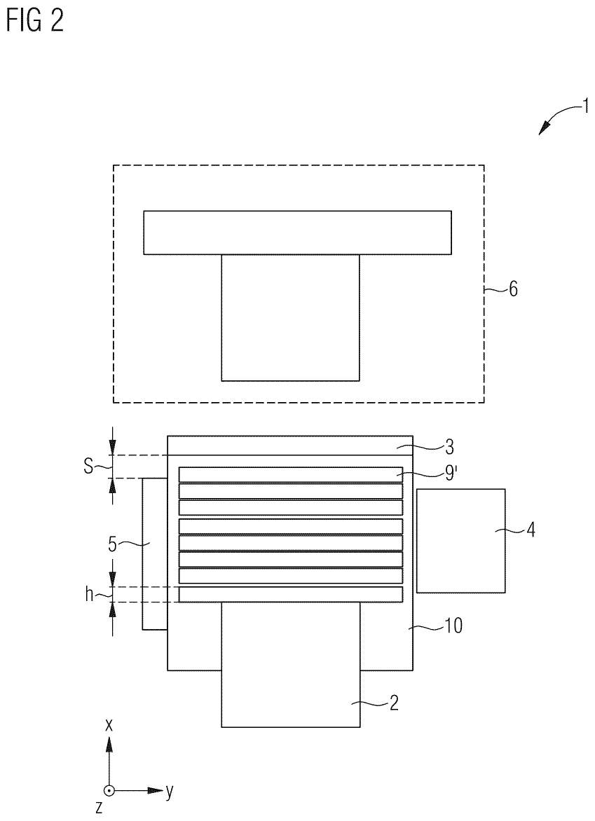

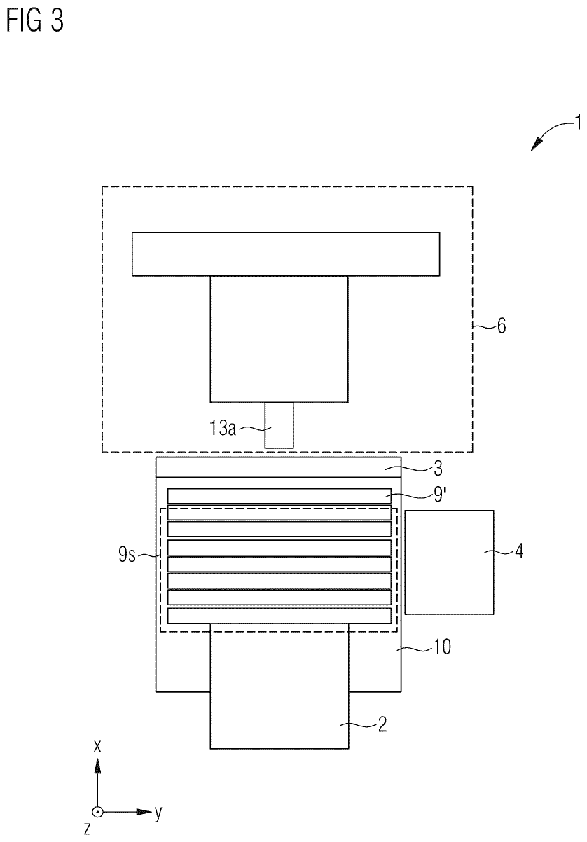

FIGS. 2 and 3 show further forms of embodiment of the proposed apparatus 1 for isolating shim elements 9 in a schematic representation. In addition to the included features of FIG. 1 these forms of embodiment of the apparatus 1 moreover have a guide element 3, a lifting apparatus 2, a selection element 5, a suction element 13a and/or magnetic element 13b and a fixing apparatus 4. The FIGS. 2 and 3 shown illustrate possible combinations of these features by way of example, so that further combinations not shown are also possible.

The guide element 3 can in particular be included in the cassette 10. The arrangement of the guide element 3 inside the apparatus 1 can in particular be provided, such that a stack of non-isolated shim elements 9 can be pressed against/onto the guide element 3 via a lifting apparatus 2. The guide element 3 can preferably be arranged at one end of the shim element stack. Other than as shown, it is also conceivable for example for the shim elements 9 to be pressed by the stack itself, or by the force of gravity. The guide element 3 can thus (other than as shown) for example also be provided at the position shown for the lifting apparatus 2, instead of the lifting apparatus 2. The shim elements 9, in particular the next shim element 9′ to be isolated, can as a result be advantageously guided by the guide element 3. This can in particular enable a predetermined horizontal sideways movement in one direction (x-direction). The guide element 3 can be designed to be non-adhesive, in particular for shim elements 9. In other words, the guide element can be designed so that it enables the shim element 9′ to be guided by a sliding movement. For this purpose, the guide element 3 can have a sliding surface with correspondingly designed surface properties. However, an embodiment of the guide element in the form of a linear roller bearing, a (circumferential) conveyor belt, a roller bearing or the like is also conceivable.

The lifting apparatus 2 can be in particular and/or at least partially included in the cassette 10. For example, a lifting platform (not shown), on which the shim elements 9 can rest, can be provided in the cassette. However, the drive of the lifting apparatus can for example be included in another component of the apparatus and/or only engage in/on the cassette 10 for power transmission. The lifting apparatus can be connected to a sensor system and/or a control unit in order to ensure continuous tracking of non-isolated shim elements 9 in the direction of the separation apparatus. For example, a completed isolation of a shim element 9′ can be detected by a sensor system and as a result a movement of the lifting apparatus 2, in particular by a gap height S (FIG. 2), can be triggered.

The selection element 5 can in particular be attached in the apparatus and/or to the cassette such that a gap S is formed between the selection element 5 and in particular (as in FIGS. 2 and 3) between the guide element 3. The selection element 5 can in particular be designed to fix the stack of non-isolated shim elements 9 in the cassette. In other words, thanks to the selection element it is possible to prevent multiple shim elements 9 from being removed at the same time. The selection element 5 can enable the gap height S to be adjusted by moving the selection element 5. Thus the gap S can advantageously be adjusted to (or greater than) the height of a shim element 9.

The separation apparatus 6 can in particular include a suction element 13a and/or magnetic element 13b. Via the suction element 13a and/or magnetic element 13b a shim element 9′ can in particular be fixed, in order to move and/or displace this shim element 9′ via the separation apparatus. The fixing of the shim element 9′ by the suction element 13a and/or magnetic element 13b can in this case in particular be effected magnetically and/or pneumatically and/or mechanically (for example by a gripper and/or slide not shown). In other words, thanks to the suction element 13a and/or magnetic element 13b a shim element can be held and separated from the stack of shim elements by a shear movement (the horizontal sideways movement).

The fixing apparatus 4 shown can in particular include a magnet. The selection element 5 can likewise be included in the fixing apparatus 4. The selection element 5 can for example also be designed in the form of a further magnet. The fixing apparatus 4, in particular the magnet, can be designed to generate a holding force, in particular a magnetic force, which holds the stack of shim elements 9 in the cassette 10. In other words, via the fixing apparatus 4, in particular the magnet, it can be ensured that only one shim element is removed out of the cassette 10. A force exerted by the horizontal sideways movement in the direction of the horizontal sideways movement (negative y-direction) can be balanced by the magnetic force generated by the magnet 4.

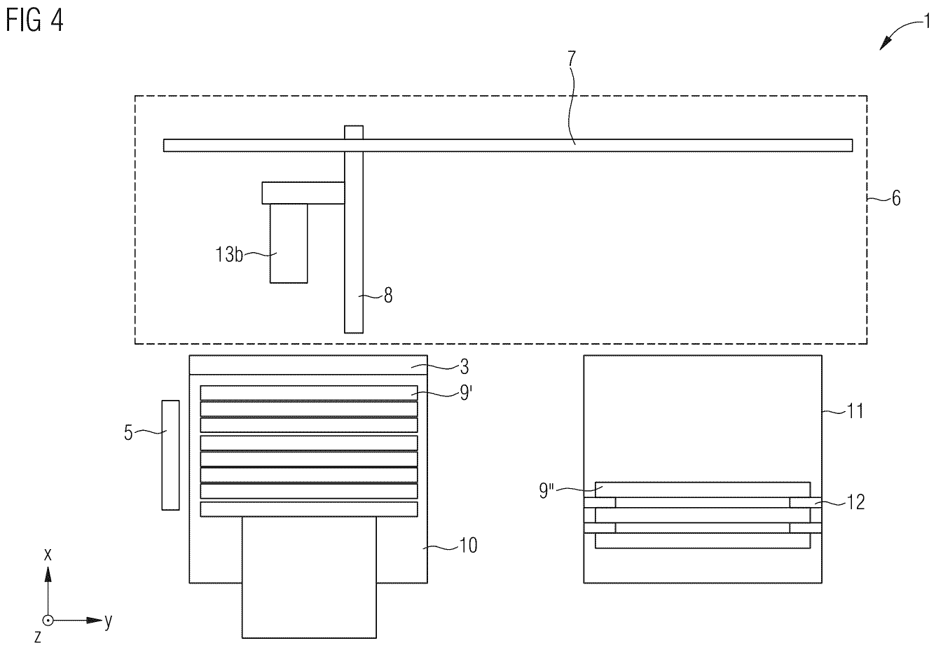

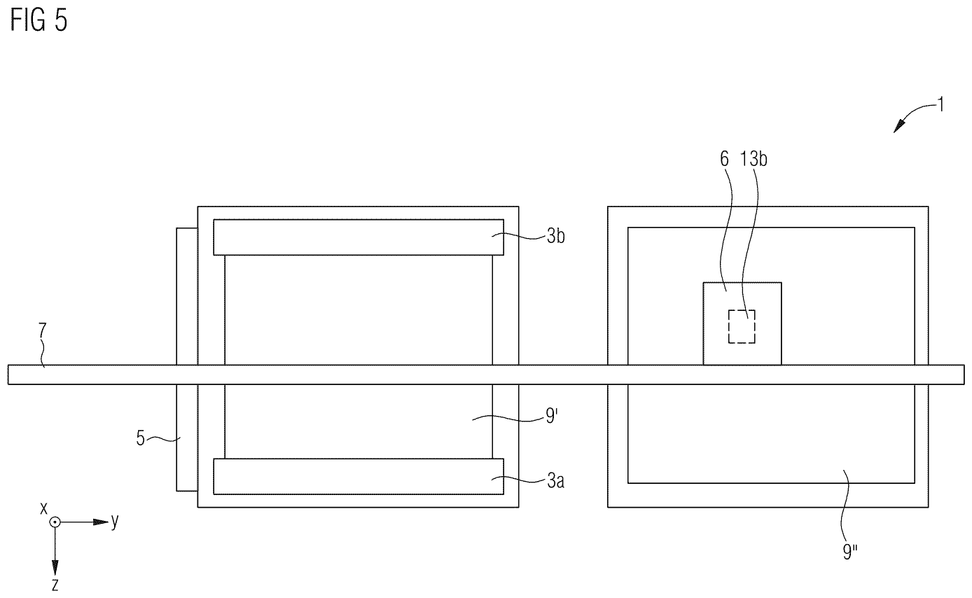

FIGS. 4 and 5 show a further form of embodiment of the proposed apparatus 1 for isolating shim elements 9 in a schematic representation in a first and second view. FIG. 4 here shows a side view (first view) of the apparatus and FIG. 5 shows a view (plan view/second view) of the apparatus rotated by 90° in the direction of the observer (or about the y-axis). In addition to the included features of FIG. 1 the apparatus in this form of embodiment includes two linear axes 7, 8 and a deposit cassette 11 containing intermediate elements 12.

The linear axes 7, 8 are advantageously in particular designed so that the vertical movement (in the x-direction) of the separation apparatus is effected by the second and a horizontal movement of the separation apparatus in a first direction (in the y-direction). A third linear axis (not shown) (in the z-direction) is for example also conceivable. The linear axes 7, 8 can moreover enable the isolated shim elements 9′ to be deposited into a deposit cassette 11. In particular, the isolated shim element 9′ can for this purpose be fixed via a suction element and/or magnetic element 13b of the separation apparatus 6 and displaced via the linear axes 7,8 to a deposit cassette 11 and/or deposited therein.

The apparatus 1 can in particular include multiple deposit cassettes 11. The deposit cassette 11 can correspond to and/or be designed identically to the cassette 10. It is however also conceivable for the deposit cassette 11 to include ledges and/or otherwise designed separation devices and/or means designed to ensure the isolation of the shim elements. For example, these separation devices and/or means can also be intermediate elements 12, which in particular can be laid into the deposit cassette 11 via the separation apparatus and/or via a further apparatus. For example, the deposit cassette 11 can moreover have a sensor to establish/display the fill level, so that the deposit cassette 11 can be replaced in the event of a predetermined fill level.

The intermediate elements 12 can in particular be plastic elements in the form of a shim element. The intermediate elements 12 can however also be a different shape and/or be made of a different material.

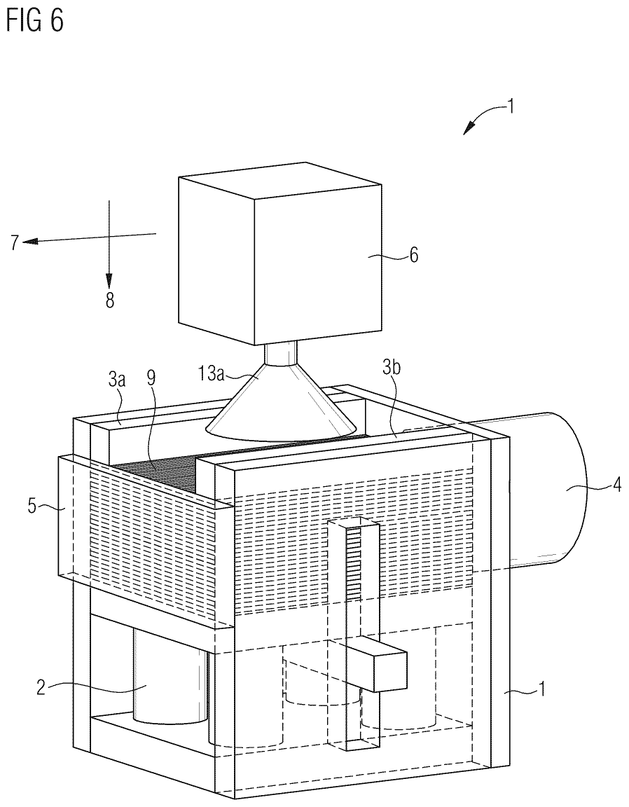

FIG. 6 shows a further form of embodiment of the proposed apparatus 1 for isolating shim elements 9 in a schematic three-dimensional representation.

The figure illustrates a preferred combination of the proposed aspects. A spatial view of an apparatus is shown, comprising a separation apparatus 6 moved by the linear axes 7, 8 (only shown schematically by arrows) with a suction cup 13a, a lifting apparatus 2 formed by 4 lifting cylinders (and/or 4 springs), a cylindrically designed magnet 4 as a fixing apparatus moreover comprising a selection element 5, and a guide apparatus 3 formed from two slide rails.

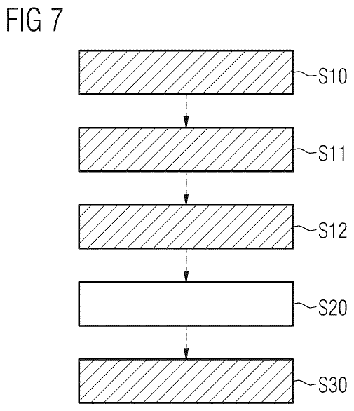

FIG. 7 shows a block diagram of a method for isolating shim elements in one form of embodiment. The method can include multiple steps, in particular S20. Further steps S11, S12, S13, S30 may be optional, represented here by hatching.

S20 comprises the removal of a shim element from the cassette via a horizontal sideways movement. S30 can comprise the deposit of an isolated shim element into a deposit cassette and/or another apparatus for storing isolated shim elements. S13 can comprise the separation and/or release of a shim element out of/from a plurality of shim elements, in particular arranged as a stack. For this purpose a shim element can optionally be fixed (S11) via a separation apparatus. Moreover, the stack of shim elements can optionally be fixed (S12) (or in other words held).

The coordinate systems drawn in the figures can likewise be selected differently than shown, for example rotated and/or with different naming of axes, and are mainly intended to illustrate the view of the apparatus.

In conclusion, reference is once again made to the fact that the methods described in detail above and the apparatus shown relate solely to exemplary embodiments that can be modified by the person skilled in the art in a variety of ways, without departing from the scope of the present invention. Further, the use of the indefinite article “a” or “an” does not rule out that the features in question may also be present multiple times. Likewise the term “unit” does not rule out that the components in question consist of multiple interacting subcomponents which if appropriate may also be distributed spatially.

Independent of the grammatical term usage, individuals with male, female or other gender identities are included within the term.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a Graphics Processing Unit (GPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

What is claimed is:

1. An apparatus for isolating shim elements, the apparatus comprising:
a cassette configured to at least one of receive or store a plurality of shim elements, wherein the plurality of shim elements are arranged in the cassette in a stack; and
a separation apparatus configured to isolate a shim element, of the plurality of shim elements, out of the cassette via a horizontal sideways movement.

2. The apparatus as claimed in claim 1, further comprising:
at least one guide element configured to guide the horizontal sideways movement of the shim element.

3. The apparatus as claimed in claim 1, further comprising:
at least one fixing apparatus configured to fix the plurality of shim elements.

4. The apparatus as claimed in claim 3, wherein the at least one fixing apparatus comprises:
at least one magnet configured to fix the plurality of shim elements in the cassette magnetically.

5. The apparatus as claimed in claim 3, wherein the at least one fixing apparatus comprises:
at least one selection element configured to fix the plurality of shim elements in the cassette mechanically.

6. The apparatus as claimed in claim 3, further comprising:
at least one guide element configured to guide the horizontal sideways movement of the shim element, wherein
the at least one fixing apparatus is arranged in respect of the cassette and the at least one guide element to form a gap between the at least one fixing apparatus and the at least one guide element, and
the gap has at least a clearance in accordance with a height of the shim element, so that the separation apparatus is configured to remove the shim element to be isolated out of the cassette through the gap.

7. The apparatus as claimed in claim 6, wherein the at least one fixing apparatus is adjustable such that the gap between the at least one fixing apparatus and the at least one guide element is adjustable as a function of the height of the shim element.

8. The apparatus as claimed in claim 1, wherein the separation apparatus comprises:
a suction element configured to fix a shim element, of the plurality of shim elements, by generating a negative pressure.

9. The apparatus as claimed in claim 1, wherein the separation apparatus comprises:
a magnetic element configured to fix a shim element, of the plurality of shim elements, magnetically.

10. The apparatus as claimed in claim 1, wherein the separation apparatus comprises:
a mechanical sliding apparatus.

11. The apparatus as claimed in claim 1, further comprising:
a lifting apparatus configured to at least one of raise or lower the plurality of shim elements in the cassette in a vertical direction.

12. The apparatus as claimed in claim 1, further comprising:
a movement apparatus including at least two linear axes, wherein
the separation apparatus is configured to be moved in a first direction and a second direction via the movement apparatus.

13. The apparatus as claimed in claim 1, further comprising:
a movement apparatus including at least one robot arm, wherein
the separation apparatus is configured to be moved via the movement apparatus.

14. The apparatus as claimed in claim 1, further comprising:
a deposit cassette configured to accommodate and stock a plurality of isolated shim elements.

15. A method for isolating shim elements via the apparatus as claimed in claim 1, wherein the method comprises:
removing at least one isolated shim element out of the cassette.

16. The apparatus according to claim 1, wherein the plurality of shim elements are arranged horizontally aligned and vertically one above another in the cassette.

17. The apparatus as claimed in claim 3, wherein the at least one fixing apparatus is configured to fix shim elements, of the plurality of shim elements, other than the shim element being isolated.

18. The apparatus as claimed in claim 4, wherein the at least one fixing apparatus is configured to fix, magnetically, shim elements, of the plurality of shim elements, other than the shim element being isolated.

19. The apparatus as claimed in claim 5, wherein the at least one fixing apparatus is configured to fix, mechanically, shim elements, of the plurality of shim elements, other than the shim element being isolated.

20. The apparatus as claimed in claim 14, wherein the deposit cassette is configured to accommodate and stock the plurality of isolated shim elements and intermediate elements.
